(19) United States
(12) Patent Application Publication
(10) Pub. No.: US 2011/0149530 A1
(43) Pub. Date: Jun. 23, 2011

(54) PRINTED CIRCUIT BOARD ASSEMBLY

(75) Inventors: Gyu Man HWANG, Yongin (KR); Dae Hyeong LEE, Seoul (KR)

(73) Assignee: SAMSUNG ELECTRO-MECHANICS CO., LTD, Gyunggi-do (KR)

(21) Appl. No.: 12/908,012

(22) Filed: Oct. 20, 2010

(30) Foreign Application Priority Data
Dec. 22, 2009 (KR) 10-2009-0129224

(51) Int. Cl. H05K 1/00

(52) U.S. Cl. 361/748

(57) ABSTRACT

There is provided a printed circuit board assembly including a printed circuit board having a plurality of circuit elements mounted on an upper surface thereof, and a power line mounted on a lower surface of the printed circuit board and supplying power to the circuit elements.

### CROSS-REFERENCE TO RELATED APPLICATIONS

This application claims the priority of Korean Patent Application No. 10-2009-0129224 filed on Dec. 22, 2009, in the Korean Intellectual Property Office, the disclosure of which is incorporated herein by reference.

### BACKGROUND OF THE INVENTION

1. Field of the Invention

The present invention relates to a printed circuit board (PCB) assembly, and more particularly, to a PCB assembly having a high degree of freedom in the arrangement of circuit elements mounted thereon and enhanced reliability.

2. Description of the Related Art

A printed circuit board (PCB) is a thin plate to which electrical elements such as an integrated circuit, a resistor, or a switch are soldered. In general, this PCB has been widely used in a variety of electronic products such as TVs, computers, cell phones, displays, communications networks, and semiconductor modules.

In recent years, with the trend of the miniaturization of electronic products, the area of a PCB used therein has gradually been decreased.

However, following such a miniaturization trend, as the demand for high performance increases, the number of circuit elements to be mounted on a PCB gradually increases.

Therefore, there is a need for a method of efficiently mounting a greater number of circuit elements on a PCB of the same area in order to realize product competitiveness.

In general, when a power line is formed on a PCB, the power line occupies part of the area of the PCB in order to pass through a point to which power is supplied. Accordingly, the area for mounting circuit elements decreases.

Also, when a level of power being supplied through the power line is high, at least a certain amount of the area needs to be ensured for the power line. Otherwise, a product reliability problem may be caused due to the generation of heat.

Therefore, there is a need for the development of technology enabling a power line to be efficiently arranged while achieving a high degree of freedom in the arrangement of circuit elements on a PCB.

### SUMMARY OF THE INVENTION

An aspect of the present invention provides a printed circuit board assembly having a high degree of freedom in the arrangement of circuit elements mounted thereon and enhanced reliability.

According to an aspect of the present invention, there is provided a printed circuit board assembly including a printed circuit board having a plurality of circuit elements mounted on an upper surface thereof, and a power line mounted on a lower surface of the printed circuit board and supplying power to the circuit elements.

The printed circuit board assembly may further include a connector mounted on the printed circuit board and being supplied with power from the outside. The power line may be connected to the connector.

The power line may be connected to a connecting terminal provided on the upper surface of the printed circuit board by penetrating the printed circuit board.

The power line may be connected to the circuit elements mounted on the upper surface of the printed circuit board by penetrating the printed circuit board.

The power line may be connected to a wiring pattern provided on the upper surface of the printed circuit board through a via provided inside the printed circuit board.

According to another aspect of the present invention, there is provided a printed circuit board assembly including: a printed circuit board having a plurality of circuit elements mounted on an upper surface thereof; a housing having the printed circuit board mounted on an upper surface thereof and including a power line receiving part; and a power line mounted in the power line receiving part and supplying power to the circuit elements.

The power line receiving part may be a recess provided in an upper or lower surface of the housing.

The power line receiving part may be a through hole provided inside the housing.

The printed circuit board assembly may further include a connector mounted on the printed circuit board and being supplied with power from the outside. The power line may be connected to the connector.

The power line may be connected to a connecting terminal provided on the upper surface of the printed circuit board by penetrating the printed circuit board.

The power line may be connected to the circuit elements mounted on the upper surface of the printed circuit board by penetrating the printed circuit board.

The power line may be connected to a wiring pattern provided on the upper surface of the printed circuit board through a via provided inside the printed circuit board.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view illustrating a printed circuit board (PCB) assembly according to an exemplary embodiment of the present invention;

FIG. 2 is a cross-sectional view illustrating the PCB assembly, taken along A-A′ of FIG. 1;

FIG. 3 is a perspective view illustrating a PCB assembly according to another exemplary embodiment of the present invention;

FIG. 4 is a cross-sectional view illustrating the PCB assembly, taken along B-B′ of FIG. 3; and

FIG. 5 is a cross-sectional view illustrating the PCB assembly, taken along C-C′ of FIG. 3.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. Detailed descriptions related to well-known functions or configurations will be ruled out in order not to unnecessarily obscure subject matters of the present invention.

In the drawings, the same reference numerals will be used throughout to designate the same or like elements.

In addition, throughout the specification, when one element is referred to as being “connected” to another element, it should be understood that the former can be “directly connected” to the latter, or “indirectly connected” to the latter via an intervening element. Also, unless explicitly described to the contrary, the word “include” and variations such as “includes” or “including,” will be understood to imply the inclusion of stated elements but not the exclusion of any other elements.

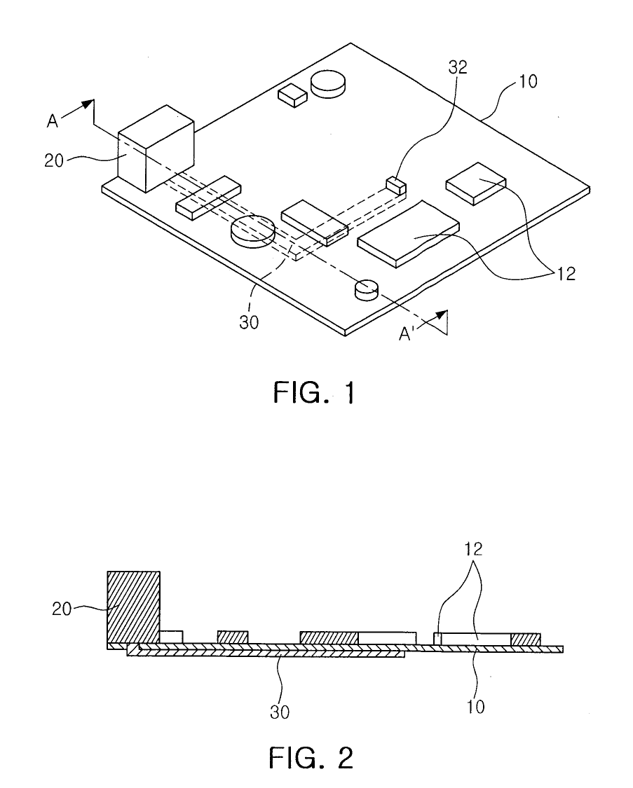

FIG. 1 is a perspective view illustrating a printed circuit board (PCB) assembly according to an exemplary embodiment of the present invention.

Referring to FIG. 1, a PCB assembly according to an embodiment of the invention may include a PCB 10, circuit elements 12, a connector 20, a power line 30, and a connecting terminal 32.

The PCB 10 may have wiring patterns formed on one surface or both surfaces thereof. The wiring patterns formed on the both surfaces may be electrically connected by a via (not shown) formed inside the PCB 10.

The circuit elements 12 may be a passive device such as a resistor, an inductor, a capacitor, or the like, or an active device such as a transistor or the like. The circuit elements 12 may be mounted on the upper surface of the PCB 10 and be electrically connected to the wiring patterns formed on the PCB.

The connector 20 may be mounted on the upper surface of the PCB.

The power line 30 may be connected to the connector 20 and be formed on the lower surface of the PCB 10. The power line 30 may supply the circuit elements 12 mounted on the PCB with power that is supplied through the connector 20 from the outside.

The connecting terminal 32 may be formed on the upper surface of the PCB 10 and be electrically connected to the wiring patterns or the circuit elements 12 disposed on the upper surface of the PCB 10 by wire bonding or soldering. The connecting terminal 32 is electrically connected to the power line 30 so that the power line 30 and the circuit elements 12 may be electrically connected to each other.

Here, the power line 30 may be electrically connected to the connecting terminal 32 by penetrating the PCB 10 at a certain point.

Otherwise, the power line 30 may be connected to the wiring patterns formed on the upper surface of the PCB 10 through the via formed inside the PCB 10.

Since the power line 30 is formed on the lower surface of the PCB 10, rather than the upper surface thereof having a plurality of circuit elements 12 mounted thereon, a mounting area for the plurality of circuit elements 12 may be ensured. Accordingly, a high degree of freedom in the arrangement of the circuit elements 12 may be achieved. That is, more circuit elements may be freely arranged on a PCB of the same area, whereby the miniaturization of a product may be achieved.

Also, the power line 30 may be formed on a sufficient space of the lower surface of the PCB 10. Therefore, when the level of supplied power is high, the width of the power line 30 may become sufficiently wide, and accordingly, a problem regarding the generation of heat or the like may be solved, thereby enhancing reliability.

FIG. 2 is a cross-sectional view illustrating the PCB assembly, taken along A-A′ of FIG. 1.

Referring to FIG. 2, the power line 30 may be extended from the connector 20 to the lower surface of the PCB 10 by penetrating the PCB 10.

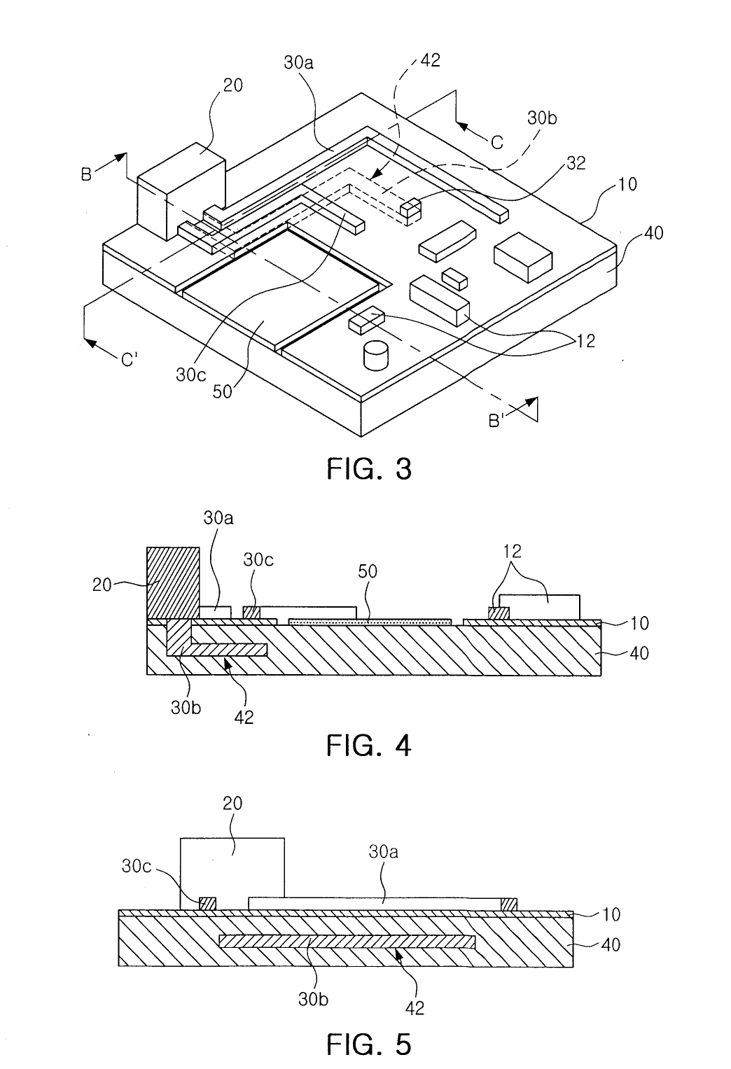

FIG. 3 is a perspective view illustrating a PCB assembly according to another exemplary embodiment of the present invention.

Referring to FIG. 3, a PCB assembly according to another embodiment of the invention may further include a housing 40 and an electronic component 50 as compared with the PCB assembly shown in FIG. 1. Hereinafter, only the differences between this embodiment of FIG. 3 and the embodiment of FIG. 1 will be described in detail.

The housing 40 may have the PCB 10 and the electronic component 50 mounted on the upper surface thereof. Also, the housing 40 may include a power line receiving part 42 formed therein so that the power line 30 may be formed in the power line receiving part 42.

As shown in FIG. 3, three power lines 30a, 30b and 30c are provided for power supply.

A single power line 30b among the three power lines is mounted in the power line receiving part 42 formed in the housing 40. FIG. 3 shows the power line receiving part 42 for a single power line. However, if desired, two or more power line receiving parts may be formed.

Referring to FIG. 3, it can be seen that a space for the forming of the three power lines 30a, 30b and 30c is insufficient on the upper surface of the PCB 10, due to a space for the mounting of the electronic component 50. When a sufficient space for the power lines is not ensured, a product reliability problem may be caused due to the generation of heat or the like. In order to solve this problem, part of the power lines, i.e., the power line 30b may be received in the housing 40.

FIGS. 4 and 5 are cross-sectional views illustrating the PCB assembly, taken along B-B′ of FIG. 3 and C-C′ of FIG. 3, respectively.

Referring to FIGS. 4 and 5, the power line receiving part 42 formed in the housing 40 may be a through hole penetrating the inside of the housing 40. Although not shown, the shape of the power line receiving part 42 is not limited thereto. The power line receiving part 42 may be a recess formed in the upper or lower surface of the housing 40.

As set forth above, in a PCB assembly according to exemplary embodiments of the invention, a high degree of freedom in the arrangement of circuit elements mounted on a PCB is achieved by forming a power line for power supply to the PCB on the lower surface of the PCB or the inside of a housing having the PCB mounted therein.

In addition, product reliability is enhanced by solving a problem such as the generation of heat by ensuring a sufficient space for a power line formed on the lower surface of a PCB or the inside of a housing having the PCB mounted therein.

While the present invention has been shown and described in connection with the exemplary embodiments, it will be apparent to those skilled in the art that modifications and variations can be made without departing from the spirit and scope of the invention as defined by the appended claims.

What is claimed is:

1. A printed circuit board assembly comprising:
a printed circuit board having a plurality of circuit elements mounted on an upper surface thereof; and
a power line mounted on a lower surface of the printed circuit board and supplying power to the circuit elements.

2. The printed circuit board assembly of claim 1, further comprising a connector mounted on the printed circuit board and being supplied with power from the outside.

3. The printed circuit board assembly of claim 1, wherein the power line is connected to a connecting terminal provided on the upper surface of the printed circuit board by penetrating the printed circuit board.

4. The printed circuit board assembly of claim 1, wherein the power line is connected to the circuit elements mounted on the upper surface of the printed circuit board by penetrating the printed circuit board.

5. The printed circuit board assembly of claim 1, wherein the power line is connected to a wiring pattern provided on the upper surface of the printed circuit board through a via provided inside the printed circuit board.

6. A printed circuit board assembly comprising:
a printed circuit board having a plurality of circuit elements mounted on an upper surface thereof;
a housing having the printed circuit board mounted on an upper surface thereof and including a power line receiving part; and
a power line mounted in the power line receiving part and supplying power to the circuit elements.

7. The printed circuit board assembly of claim 6, wherein the power line receiving part is a recess provided in an upper or lower surface of the housing.

8. The printed circuit board assembly of claim 6, wherein the power line receiving part is a through hole provided inside the housing.

9. The printed circuit board assembly of claim 6, further comprising a connector mounted on the printed circuit board and being supplied with power from the outside.

10. The printed circuit board assembly of claim 6, wherein the power line is connected to a connecting terminal provided on the upper surface of the printed circuit board by penetrating the printed circuit board.

11. The printed circuit board assembly of claim 6, wherein the power line is connected to the circuit elements mounted on the upper surface of the printed circuit board by penetrating the printed circuit board.

12. The printed circuit board assembly of claim 6, wherein the power line is connected to a wiring pattern provided on the upper surface of the printed circuit board through a via provided inside the printed circuit board.
